(19) United States
(12) Patent Application Publication
(10) Pub. No.: US 2014/0319677 A1
(43) Pub. Date: Oct. 30, 2014

(54) SUBMOUNT FOR ELECTRONIC, OPTOELECTRONIC, OPTICAL, OR PHOTONIC COMPONENTS

(71) Applicants: Rolf A. Wyss, Glendale, CA (US); Peter C. Sercel, Pasadena, CA (US)

(72) Inventors: Rolf A. Wyss, Glendale, CA (US); Peter C. Sercel, Pasadena, CA (US)

(73) Assignee: HOYA CORPORATION USA, Santa Clara, CA (US)

(21) Appl. No.: 14/006,668

(22) PCT Filed: Jun. 8, 2012
(86) PCT No.: PCT/US2012/041774

§ 371 Date: Sep. 21, 2013

(51) Int. Cl. H01L 23/00; H01L 33/62; H01L 31/02

(52) U.S. Cl. CPC H01L 24/14; H01L 31/02005; H01L 33/62
USPC 257/737

(57) ABSTRACT

One or more metal contacts are formed in a recessed area on a top surface of a submount; a pickup tool of a die bonder engages protruding peripheral regions of the submount so as not to damage the metal contacts or metal bumps in the recessed region. A semiconductor optical submount includes non-contiguous dielectric layers between metal contacts and the semiconductor material to reduce parasitic capacitance.

### FIELD OF THE INVENTION

The field of the present invention relates to submounts for electronic, optoelectronic, optical, or photonic components. In particular, submounts are disclosed herein that (i) facilitate assembly with a substrate using a die bonder or (ii) exhibit reduced electrical capacitance.

### BACKGROUND

Submounts are employed in a variety of circumstances to indirectly attach to a substrate and to support an electronic, optoelectronic, optical, or photonic component. The submount can serve one or more purposes, including but not limited to: mechanical support, positioning or alignment, heat dissipation, optical signal redirection, or electrical connection. One example is disclosed in, e.g., U.S. Pat. No. 6,921,956 entitled “Optical apparatus using vertical light receiving element” issued Jul. 26, 2005 to Yang et al.

### SUMMARY

A submount is formed from a volume of solid submount material. A top surface of the submount includes one or more metal contacts formed on corresponding contact areas. The metal contacts are arranged for attaching a component to the top surface of the submount. The contact areas are positioned on a region of the submount top surface that is (i) recessed relative to one or more protruding regions of the submount top surface and (ii) sized and shaped to accommodate the attached component positioned at least partly within the recessed region. The protruding regions form a surface for engaging a pickup tool of a die bonder and enabling the die bonder to attach the submount to the substrate without substantial contact between the pickup tool and the recessed region.

An optical submount is formed from a volume of semiconductor material that is substantially transparent over an operational wavelength range. The submount is arranged to direct or transmit a portion of an optical signal to propagate within the volume of semiconductor material so that at least a portion of the optical signal is transmitted through a transmission area of a top surface of the submount. The top surface of the submount includes two or more separate metal contacts formed on corresponding contact areas that are distinct from the transmission area. The metal contacts are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor. The top surface of the submount includes a corresponding area of a first dielectric layer between each metal contact and the semiconductor material. The areas of the first dielectric layer are non-contiguous thereby causing the metal contacts to exhibit reduced capacitance relative to capacitance exhibited with a single contiguous area of the first dielectric layer extending between two or more of the metal contacts and the semiconductor material.

Objects and advantages pertaining to submounts may become apparent upon referring to the exemplary embodiments illustrated in the drawings and disclosed in the following written description or appended claims.

This summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 illustrates schematically a perspective view of an exemplary submount.

FIG. 2 illustrates schematically a top view of the submount of FIG. 1.

FIG. 3 illustrates schematically a side view of the submount of FIG. 1.

FIG. 4 illustrates schematically a side cross sectional view of the submount of FIG. 1.

FIG. 5 illustrates schematically a side cross sectional view of the submount of FIG. 1 and a mounted component.

FIG. 6 illustrates schematically a side cross sectional view of the submount of FIG. 1 engaged with a pickup tool of a die bonder.

FIG. 7 illustrates schematically a perspective view of another exemplary submount.

FIG. 8 illustrates schematically a side cross sectional view of another exemplary submount.

FIG. 9 illustrates schematically a side cross sectional view of another exemplary submount.

FIG. 10 illustrates schematically a side view of an exemplary optical submount.

FIG. 11 illustrates schematically a side view of another exemplary optical submount.

FIG. 12 illustrates schematically a side view of another exemplary optical submount.

FIG. 13 illustrates schematically a side view of another exemplary optical submount.

FIG. 14 illustrates schematically a side view of an exemplary optical submount and a mounted component.

FIG. 15 illustrates schematically a side view of an exemplary optical submount and a mounted component.

FIGS. 16A and 16B illustrate schematically top and side views, respectively, of an exemplary optical submount. FIG. 16C is a plot of measured capacitance as a function of bias voltage of the submount of FIGS. 16A/B.

FIGS. 17A and 17B illustrate schematically top and side views, respectively, of another exemplary optical submount. FIG. 17C is a plot of measured capacitance as a function of bias voltage of the submount of FIGS. 17A/B.

FIGS. 18A and 18B illustrate schematically top and side views, respectively, of another exemplary optical submount. FIG. 18C is a plot of measured capacitance as a function of bias voltage of the submount of FIGS. 18A/B.

FIGS. 19A and 19B illustrate schematically top and side views, respectively, of another exemplary optical submount. FIG. 19C is a plot of measured capacitance as a function of bias voltage of the submount of FIGS. 19A/B.

It should be noted that the embodiments depicted in this disclosure are shown only schematically, and that not all features may be shown in full detail or in proper proportion. Certain features or structures may be exaggerated relative to others for clarity. It should be noted further that the embodiments shown are exemplary only, and should not be construed as limiting the scope of the written description or appended claims.

### DETAILED DESCRIPTION OF EMBODIMENTS

A submount is sometimes employed to attach a component to a substrate indirectly; the component is attached to the submount and the submount is attached to the substrate. Submounts are employed in a variety of circumstances to indirectly attach to a substrate an electronic, optoelectronic, optical, or photonic component. The submount can serve one or more purposes, including but not limited to: mechanical support, positioning or alignment, heat dissipation, optical signal redirection or transmission (in which case it might be referred to as an optical submount), or electrical connection. Attachments can be made using adhesive, solder, or other suitable means. If solder is employed, metallized areas (i.e., metal contacts) are needed to allow the solder to adhere to a nonmetallic substrate, submount, or component. Such a metal contact and solder can be employed to provide only mechanical attachment, or can be employed to provide an electrical or thermal conduction path between the attached elements (e.g., component to submount or submount to substrate) in addition to providing mechanical attachment.

In many cases high speed performance is desired for conditioning or processing an electrical signal, for converting optical signals to electrical signals (e.g., using a photodiode or other photodetector), or for converting electrical signals into optical signals (e.g., using a laser diode or other light source). High speed performance may require bit rates on the order of 10⁸-10¹¹ bits/second or more for digital signals or bandwidths on the order of 10⁸-10¹¹ Hz for analog signals. To achieve such high speed performance, parasitic capacitance, inductance, and resistance must be kept below certain levels. In some instances parasitic capacitance of only a few tenths of a picofarad or less can significantly degrade the performance of a high speed component or circuit (e.g., by limiting bandwidth or by causing crosstalk). Miniaturization of components or assemblies can exacerbate the problem, because smaller distances between circuit elements can give rise to larger unintended or unwanted capacitance or inductance. Metal contacts formed on components fabricated from semiconductor materials (separated from the semiconductor by a dielectric layer to prevent unwanted electrical conduction) naturally act as capacitors and can contribute significantly to parasitic capacitance. An optical submount fabricated from semiconductor material and secured to its optoelectronic component using metal contacts and solder can therefore act as a source of unwanted capacitance, and it is therefore desirable to arrange the submount and its metal contacts to reduce such capacitance.

It is often desirable to employ standard chip or die bonders to position and attach an electronic, optoelectronic, photonic, or optical component to a substrate. Such bonders often employ a vacuum chuck or other suitable pickup tool to grasp the component, move it to and position it on the substrate, and hold it there while it is attached to the substrate. Some components are extremely small (e.g., a few hundred microns in width or length), in which case the vacuum chuck may take the form of a narrow capillary tube or a blunt needle. The end of the vacuum chuck and the top surface of the component come into contact and are subject to mechanical forces and stresses in the course of securing the component on the chuck and then placing it on the substrate. The component should tolerate the contact without becoming damaged. A die bonder is similarly employed to position and attach a submount to a substrate, typically before the corresponding component is positioned on and attached to the submount (also with the die bonder). The top surface of the submount is often provided with metal contacts and metal bumps on the contacts to facilitate later attachment of the corresponding component. Those metal contacts and metal bumps often can be damaged easily by contact with the vacuum chuck or other pickup tool of the die bonder during the submount's placement on and attachment to the substrate. It is therefore desirable to arrange the submount to reduce the likelihood of such damage to the metal contacts or metal bumps on its top surface.

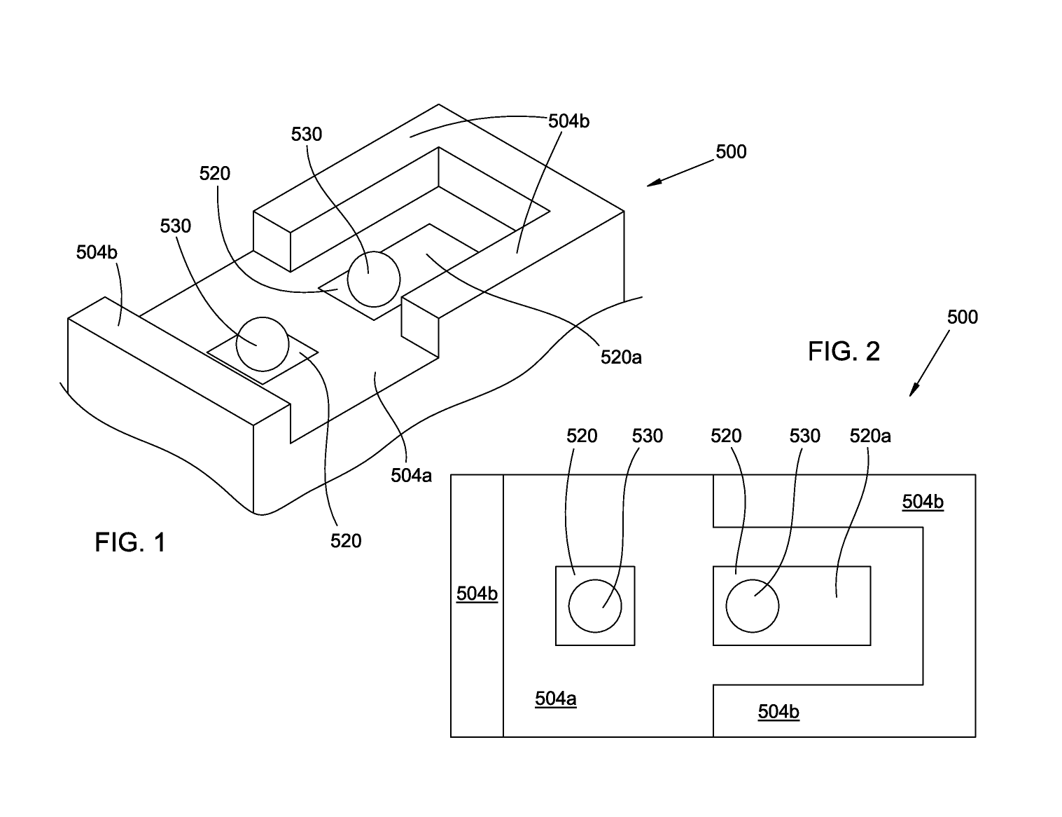

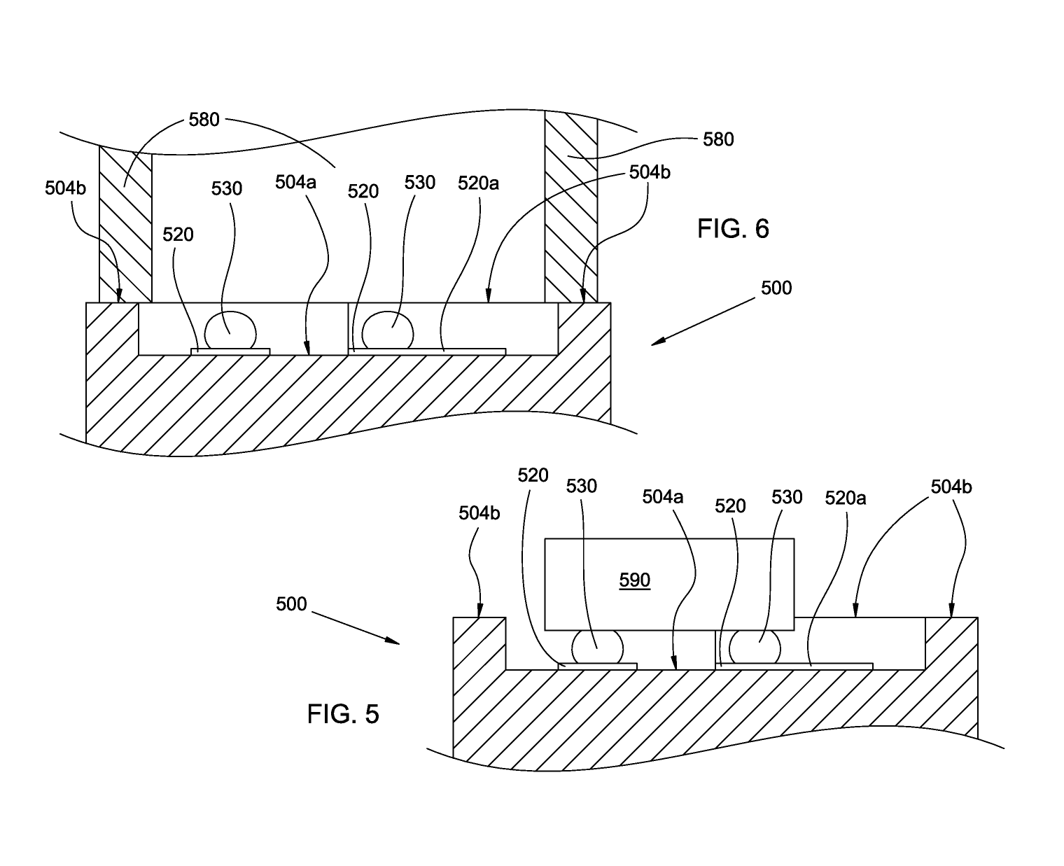

Exemplary embodiments of a submount 500 that are arranged to facilitate placement and attachment by a chip or die bonder are illustrated schematically in FIGS. 1-9. The submount 500 comprises a volume of solid material. The bottom surface of the submount 500 can be arranged in any suitable way to be attached to a substrate (bottom surface and substrate not shown). The top surface of the submount 500 includes one or more metal contacts 520 formed on corresponding contact areas. Two metal contacts 520 are shown in FIGS. 1-9; any suitable number of one or more metal contacts 520 can be employed. The metal contacts 520 are arranged for attaching a component 590 to the top surface of the submount 500 (FIG. 5). The component 590 can comprise an electronic, optoelectronic, photonic, optical, or other component. In addition to providing a point of mechanical attachment for the component 590, the metal contacts 520 can in some embodiments also be employed to provide an electrical or thermal conduction path between the component 590 and the submount 500. If used for an electrical connection, one or more of the metal contacts 520 can include a wire-bonding area 520a to facilitate an electrical connection to the component 590 via the metal contact 520, if needed or desired.

The one or more contact areas are positioned on a region 504a of the submount top surface that is recessed relative to one or more protruding regions 504b of the submount top surface. The recessed region 504a is sized and shaped to accommodate the attached component 590 positioned at least partly within the recessed region 504a (FIG. 5). One or more of the protruding regions 504b (which are preferably, but not necessarily, substantially coplanar) form a surface for engaging a pickup tool of a die bonder (e.g., a vacuum chuck 580) and enabling the die bonder to attach the submount 500 to a substrate without substantial contact between the pickup tool and the recessed region 504a (FIG. 6).

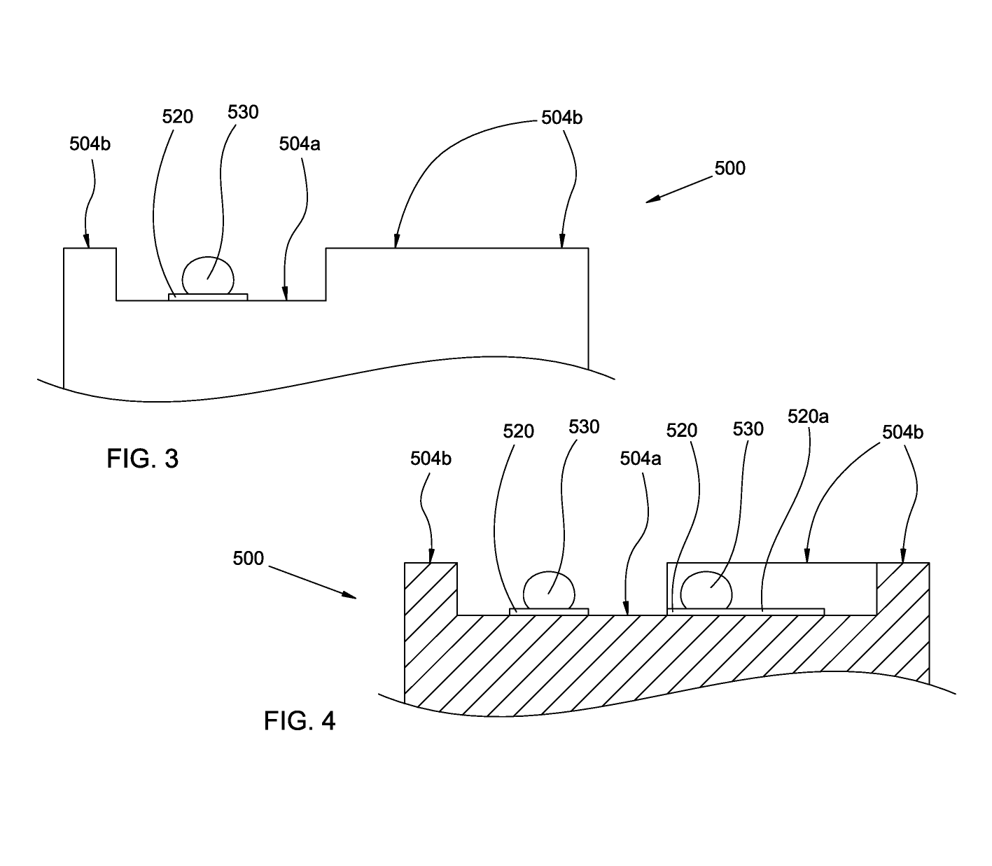

The recessed region 504a and the one or more protruding regions 504b on the top surface of the submount 500 can be arranged in any suitable way commensurate with the nature or arrangement of the metal contacts 520, component 590, or other structures on the top surface of the submount 500. The size and shape of the recessed region 504a can enable the component 590 to be at least partly received within the recessed region 504a (FIG. 5). The height of the protruding regions 504b relative to the recessed region 504a should be sufficient so that no structure formed on the recessed region 504a makes substantial contact with the vacuum chuck 580 when it engages the protruding regions 504b (FIG. 6). In the exemplary embodiment, each metal contact 520 has formed thereon one or more corresponding metal bumps 530. Metal bumps comprising gold or a gold alloy, aluminum or an aluminum alloy, solder of any suitable type or composition, or other suitable metal or metal alloy are often employed for facilitating attachment of components or submounts using a chip or die bonder, but are subject to deformation or damage as a result contact with the vacuum chuck 580 of the die bonder. In the exemplary embodiments, none of the metal bumps 530 extends upward beyond the engagement surface of the one or more protruding regions 504b (FIGS. 3 and 4). By virtue of that arrangement, the die bonder can be used to attach the submount 500 to a substrate without substantial contact between the pickup tool (e.g., the vacuum chuck 580) and the one or more metal bumps 530 (FIG. 6). Substantial elimination of contact between the vacuum chuck 580 and the metal bumps 530 or metal contacts 520 reduces or eliminates the likelihood damage to the metal bumps 530 or metal contacts 520 arising from such contact.

Generally, the submount 500 can comprise a volume of any suitable solid material; suitability can be determined by any one or more of availability, cost, ease of processing, dimensional stability, thermal or electrical transport properties, or other relevant material property or parameter. Examples include a semiconductor material (e.g., doped or undoped silicon or another doped or undoped Group IV semiconductor, a doped or undoped III-V semiconductor, or a doped or undoped II-VI semiconductor), a dielectric material (e.g., a glassy material, a crystalline material, a ceramic material, a metal oxide, or a semiconductor oxide), or a metal or metal alloy. The choice of material can be at least partly determined by functionality to be provided by the submount (if any). For example, metallic material might be best suited if the submount is to function as a heat sink. If submount 500 is an optical submount arranged to direct or transmit an optical signal propagating within it (e.g., for supporting a photodetector, light source, or other optoelectronic, photonic, or optical component), then a material typically is chosen that is substantially transparent over a suitable operational wavelength range. Semiconductor or dielectric materials can be well suited for forming an optical submount. Semiconductor material can be employed for an operational wavelength range that extends, e.g., from about 1.2 μm to about 1.7 μm. Dielectric material can be employed for an operational wavelength range that extends, e.g., from about 0.4 μm to about 2 μm. Other materials or other operational wavelength ranges can be employed.

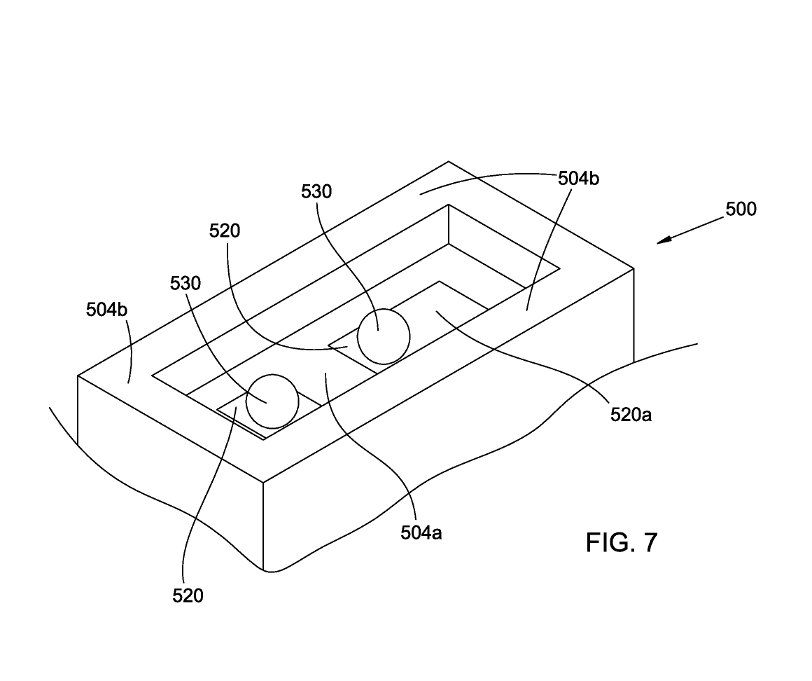

The size and shape of the recessed region 504a enables the component 590 to be at least partly received within the recessed region 504a (FIG. 5). In some embodiments, the recessed area 504a is circumscribed by a protruding region 504b that is arranged as a closed ring (FIG. 7). In other embodiments, the recessed region 504a is not circumscribed by a protruding region 504b. Instead, one or more of the protruding regions 504b can be arranged around one or more portions of the periphery of the recessed area 504a (FIGS. 1-6).

In some embodiments, the one or more protruding regions 504b are formed from the same material that makes up the bulk of the submount 500 (FIGS. 4-6). In one example, the recessed region 504a can be formed by spatially selective etching, leaving behind protruding regions 504b that comprise the submount material. Many semiconductor materials and dielectric materials are readily amenable to such spatially selective etching. In another example, additional material (the same material that forms the bulk of the submount 500) can be spatially selectively deposited to form the protruding regions 504b.

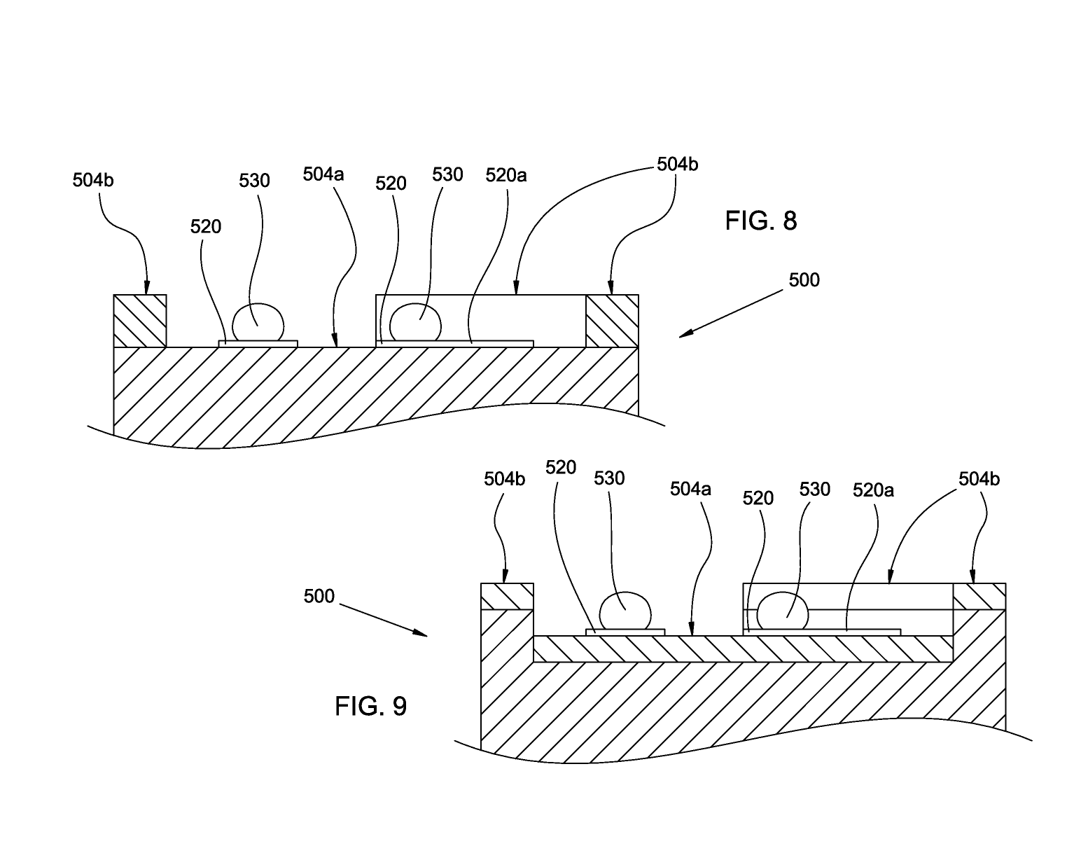

In some other embodiments, the one or more protruding regions 504b can include one or more materials different from the material that forms the bulk of the submount 500 (different with respect to composition, e.g., semiconductor versus oxide, or different with respect to morphology, e.g., crystalline versus amorphous forms having the same composition). In some examples, the entire protruding portions 504b comprise material different from that of the submount 500 (FIG. 8). In other examples, the protruding portions 504b include some material of the bulk of the submount 500 along with some material different from the bulk of the submount 500 (FIG. 9). In any of those examples, the one or more different materials can be absent from or present on the recessed region 504a; if present on recessed region 504a, the thickness of the one or more different materials can be the same as that on the protruding regions 504b, or different. Suitable materials for forming the protruding regions 504b can include but are not limited to one or more of (i) glassy material, (ii) crystalline material, (iii) ceramic material, (iv) metal or metal alloy, (v) semiconductor material, (vi) metal oxide, nitride, or oxynitride, or (vii) semiconductor oxide, nitride, or oxynitride. One suitable exemplary combination of materials includes a semiconductor material that forms the bulk of the submount 500 and a semiconductor or metal oxide that forms at least a portion of the protruding regions 504b. In some examples, a differing material layer can be spatially selectively deposited, or can be uniformly grown or deposited and then spatially selectively etched, to form the protruding regions 504b on the top surface of the submount 500. In some other examples, the protruding regions 504b can be partly formed from the material of the bulk of the submount 500, and then a substantially uniform layer of a different material can be deposited or grown on the entire top surface; the material deposited or grown is then present on both the protruding regions 504b as well as on the recessed region 504a. Whatever the sequence or arrangement of growing, depositing, etching, or other processing to form the protruding regions 504b and the recessed region 504a, further processing steps can be performed as needed or desired to form or modify other structural features of the submount 500.

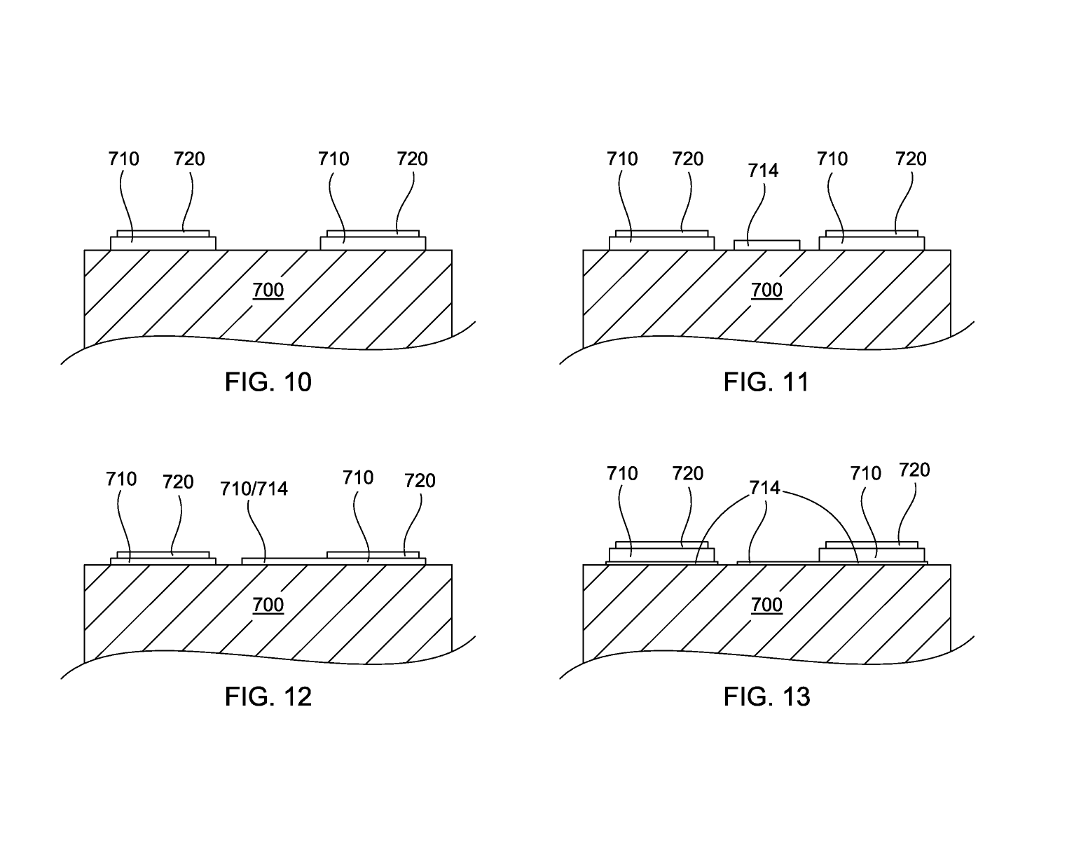

Exemplary embodiments of a semiconductor optical submount 700 that are arranged to exhibit reduced capacitance are illustrated schematically in FIGS. 10-15. The optical submount 700 comprises a volume of semiconductor material that is substantially transparent over an operational wavelength range; examples of suitable semiconductor materials and wavelength ranges are given above. The bottom surface of the submount 700 can be arranged in any suitable way to be attached to a substrate (bottom surface and substrate not shown). The optical submount 700 is arranged to direct or transmit a portion of an optical signal to propagate within the volume of semiconductor material so that at least a portion of the optical signal is transmitted through a transmission area of a top surface of the submount 700.

A bottom surface (not shown) of the submount 700 can be arranged in any suitable way to be attached to substrate (not shown). The submount 700 can be arranged in any suitable way so that an optical signal can be directed or transmitted through the transmission area of the submount top surface. Direction or transmission of the propagating optical signal can be achieved by a variety of arrangements (none shown), and can include one or more of, e.g., internal or external reflection from a facet of the submount 700, refraction upon transmission into or out of the submount 700, or reflection or refraction by another optical element.

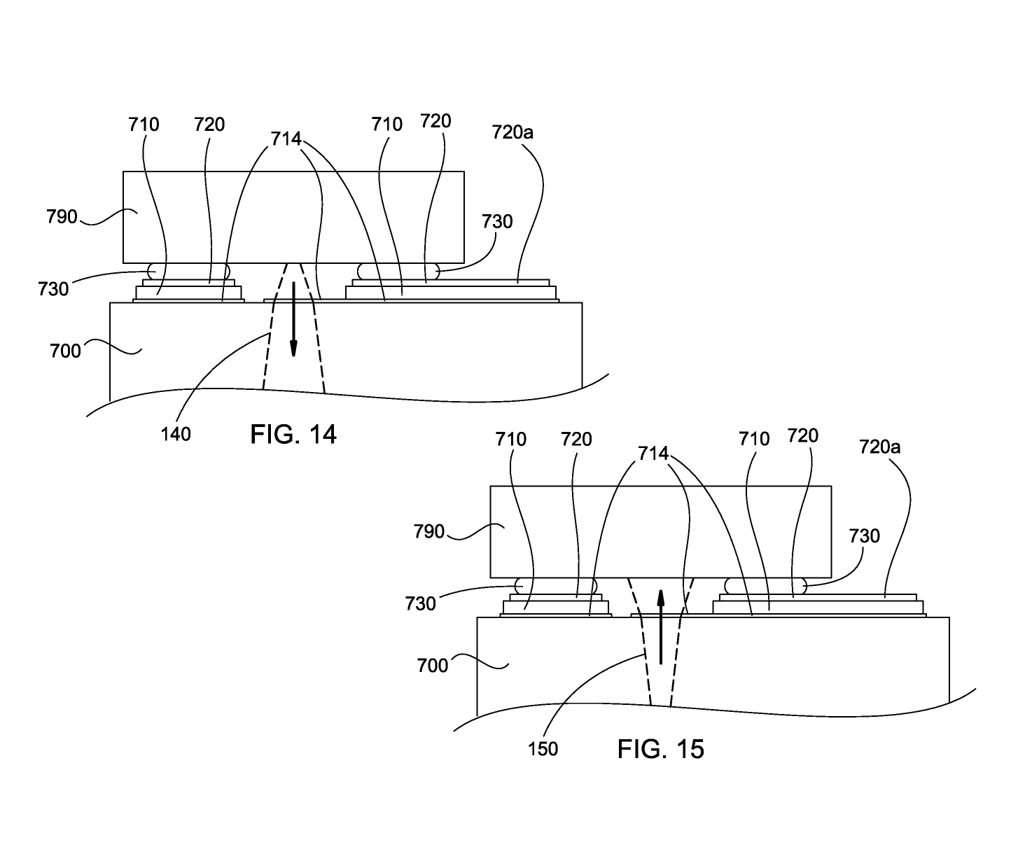

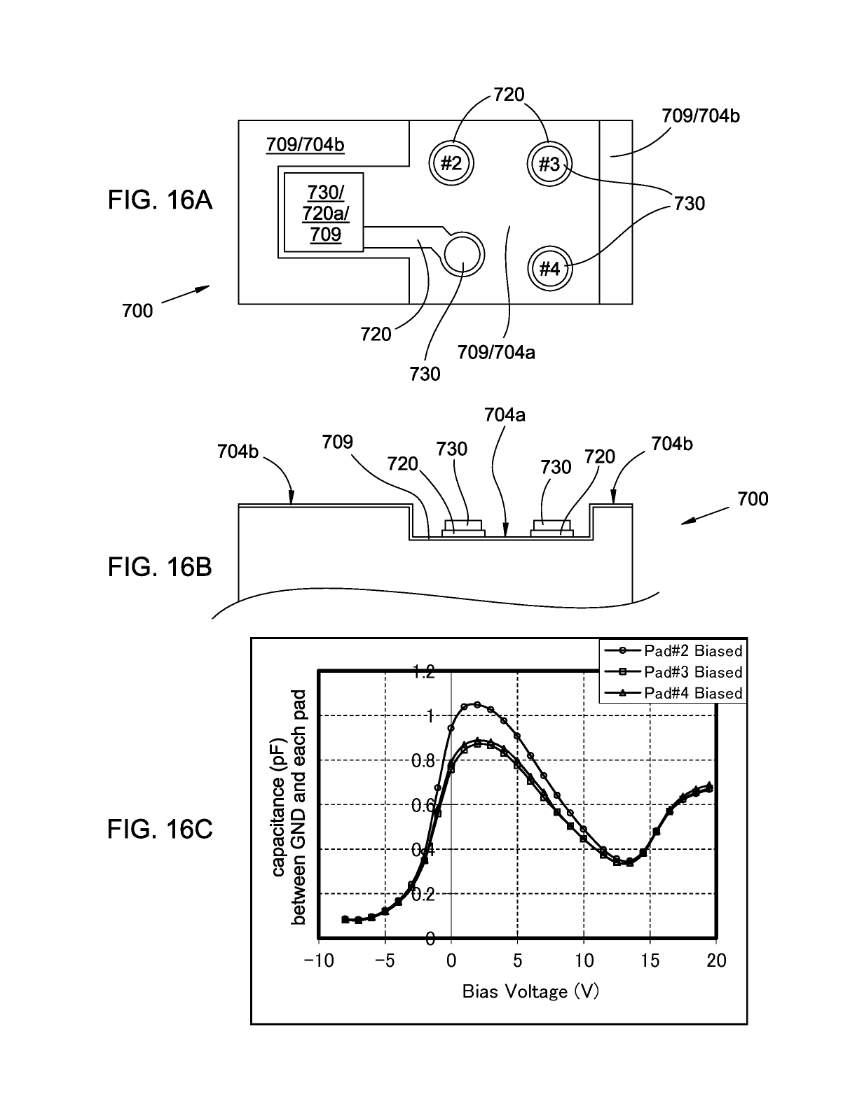

The top surface of the submount 700 includes two or more metal contacts 720 formed on corresponding contact areas. Two metal contacts 720 are shown in FIGS. 10-15; four metal contacts 720 are shown in FIGS. 16A, 17A, 18A, and 19A; any suitable number of one or more metal contacts 720 can be employed. The metal contacts 720 are arranged for attaching a component 790 to the top surface of the submount 700 (FIGS. 14 and 15); in some examples, metal bumps 730 can be employed. The component 790 can comprise an electronic, optoelectronic, photonic, optical, or other component. In some examples the component 790 comprises a laser diode or other light source arranged to launch an optical signal 140 so that a portion of the optical signal enters the optical submount 700 through a transmission area 701 on the top surface of the submount 700 (FIG. 14). In other examples the component 790 comprises a photodiode (e.g., p-i-n or avalanche) or other photodetector arranged to receive a portion of an optical signal 150 that exits the optical submount 700 through the transmission area 701 (FIG. 15). In addition to providing a point of mechanical attachment for the component 790, at least one of the metal contacts 720 can also be employed in some embodiments to provide an electrical conduction path between the component 790 and the submount 700. If used for an electrical connection, one or more of the metal contacts 720 can include a wire-bonding area 720a to facilitate an electrical connection to the component 790 via the metal contact 720, if needed or desired. One or more of the metal contacts can also be employed to provide a thermal conduction path between the component 790 and the optical submount 700.

In the case of the presently disclosed optical submounts, electrical conductivity between the semiconductor optical submount 700 and the metal contacts 720 is not desired. Dielectric layers are conventionally employed as insulators between metallic material and semiconductor material when electrical conduction between the metal and semiconductor is not desired. It has been observed that such a metal-insulator-semiconductor structure can act as a capacitor. Each metal contact 720 and its corresponding area of the contiguous dielectric layer 709 (FIGS. 16A and 16B) can therefore act as a source of unwanted capacitance that can degrade high-speed performance of the component 790 (FIG. 16C). Conventional submounts have been constructed with a contiguous dielectric layer 709 on the top surface of the submount with the metal contacts 720 formed on corresponding areas of the contiguous dielectric layer 709 (FIGS. 16A and 16B).

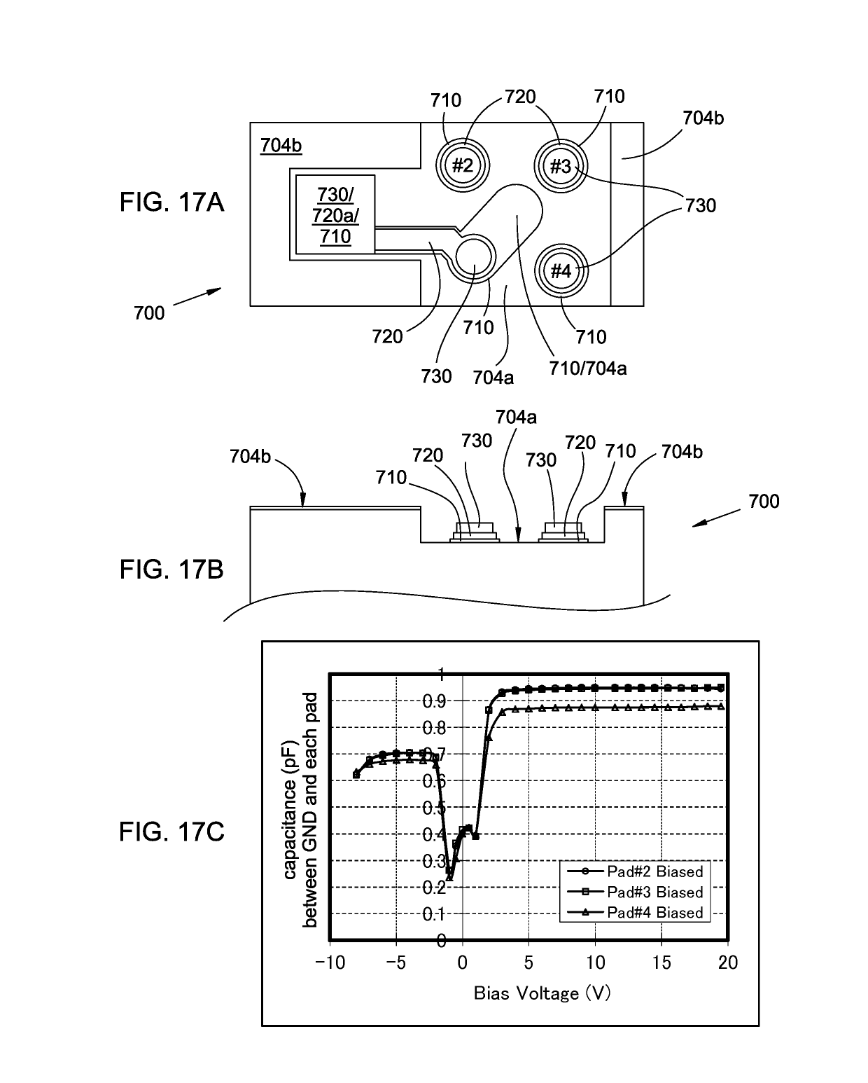

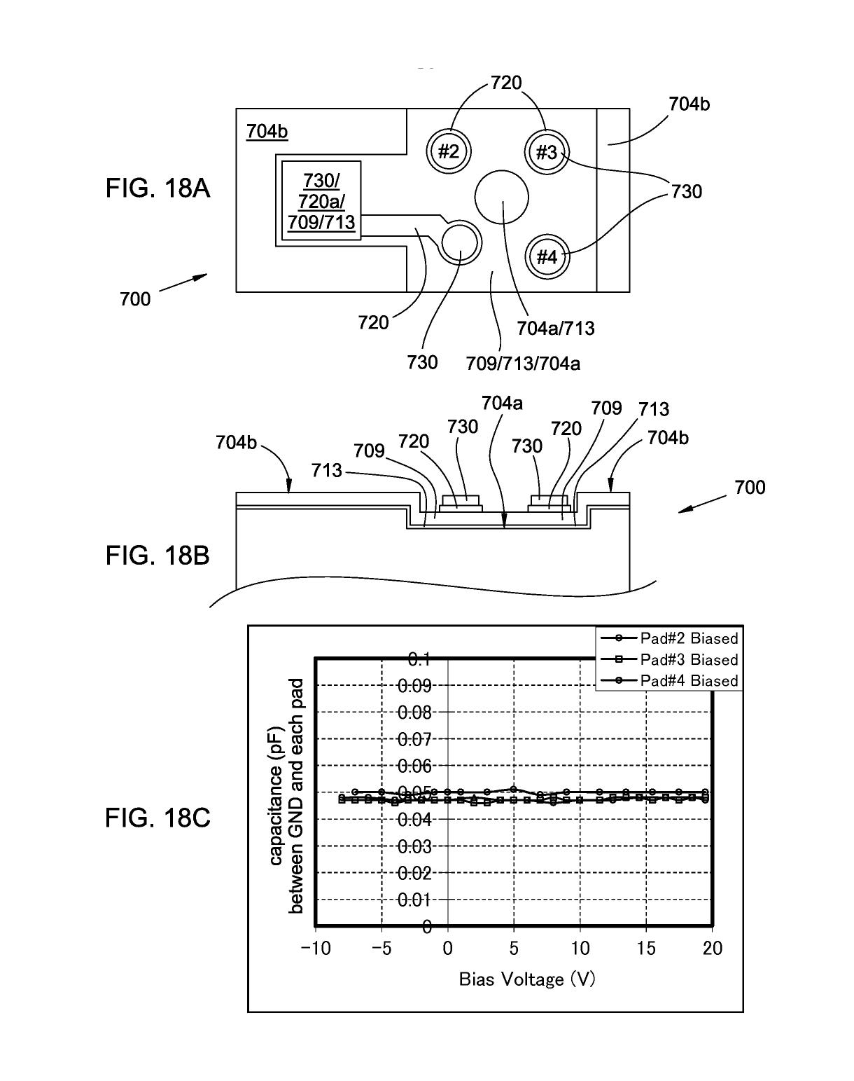

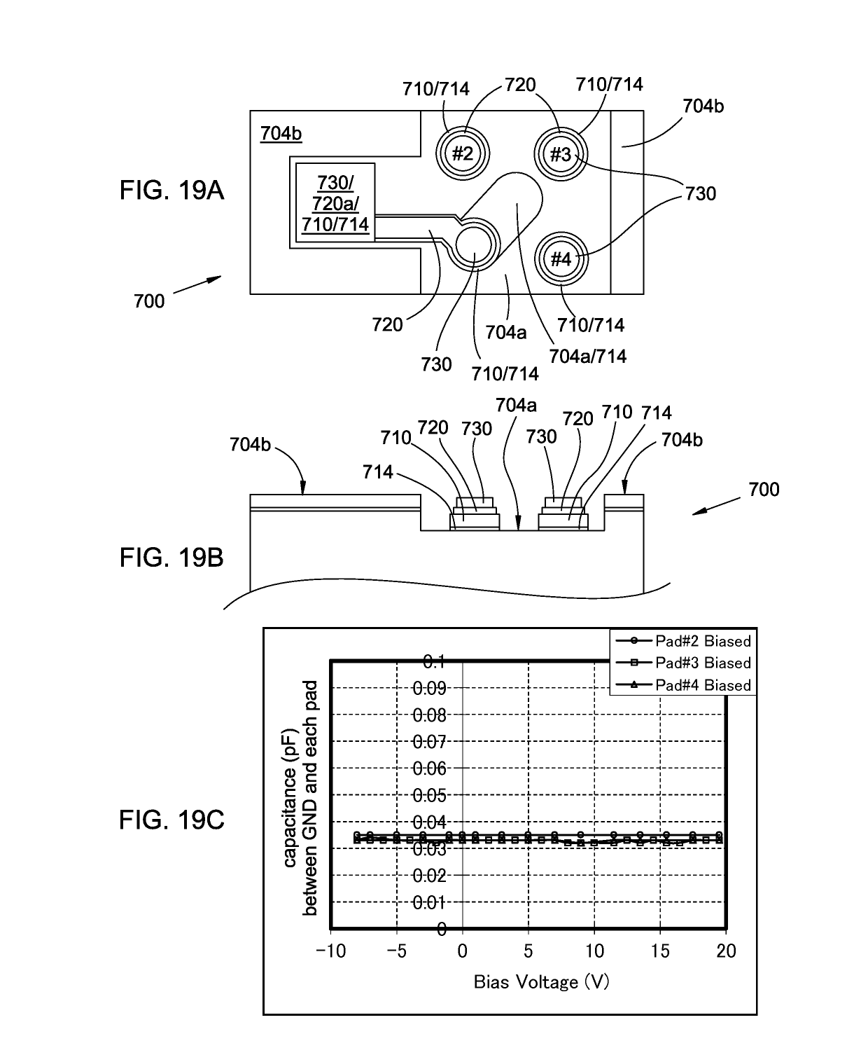

In the presently disclosed optical semiconductor submounts, each one of the metal contacts 720 is separated from the top surface of the semiconductor material of the submount 700 by a corresponding area of a dielectric layer 710. The areas of the dielectric layer 710 are non-contiguous (i.e., they form separate “islands” on the top of the submount 700; FIGS. 17A and 17B). The non-contiguous arrangement can be achieved by spatially selective growth or deposition of the areas of dielectric layer 710, or by growth or deposition over a wider area followed by spatially selective removal of portions of the dielectric layer 710 (e.g., by etching). The non-contiguous arrangement of the areas of dielectric layer 710 cause the metal contacts to exhibit reduced capacitance relative to capacitance exhibited with a contiguous dielectric layer 709 extending between two or more of the metal contacts 720 and the semiconductor material (FIG. 16C versus FIG. 17C; FIG. 18C versus FIG. 19C). Even a small reduction in capacitance (e.g., about 0.1 pF) can improve the high-speed performance of component 790. In one example of an avalanche photodiode (having a capacitance of ca. 0.35 pF) mounted on the submount and coupled to a transimpedance amplifier (having an impedance of ca. 20 kΩ), model calculations yield an improvement of about 0.2 dB to about 0.7 dB in the sensitivity of the avalanche photodiode if the stray capacitance is reduced by about 0.1 pF. The improvement in sensitivity observed in a given situation can vary widely depending on the detailed nature, properties, and arrangement of the photodetector, submount, amplifier, or other coupled electronics.

The dielectric layers 710 can comprise any suitable dielectric material that is compatible with the semiconductor material of the submount 700. Examples include metal oxides, nitrides, or oxynitrides or semiconductor oxides, nitrides, or oxynitrides. One specific example comprises a dielectric layer 710 comprising silica (i.e., silicon oxide, doped or undoped) on a semiconductor submount comprising silicon (doped or undoped). Greater reduction in capacitance results from thicker dielectric layers 710 (up to a point). In some examples, the dielectric layers 710 are greater than about 1 μm thick or greater than about 2 μm thick.

In some embodiments, the semiconductor optical submount 700 can include a dielectric anti-reflection layer 714 on the transmission area of the submount top surface. In some examples, the anti-reflection layer 714 has the same thickness and material composition as the dielectric layers 710. In such examples, the anti-reflection layer 714 can be non-contiguous with all of the dielectric layers 710 (FIG. 11) or can be contiguous with at most one of them (FIG. 12). In other examples, the dielectric anti-reflection layer 714 differs from the dielectric layers 710 with respect to material composition or thickness. In those examples, the dielectric layers 710 and the anti-reflection layer 714 can occupy non-contiguous areas (FIG. 11) or corresponding areas of the anti-reflection layer 714 can be present between the dielectric layers 710 and the semiconductor material (FIG. 13). In that latter arrangement, the anti-reflection layer 714 on the transmission area can be contiguous with at most one of the areas of the anti-reflection layer 714 beneath one of the dielectric layers 710. The non-contiguous arrangement of areas of the anti-reflection layer 714 can be achieved by spatially selective growth or deposition of the areas of the anti-reflection layer 714, or by growth or deposition over a wider area followed by spatially selective removal of portions of the anti-reflection layer 714 (e.g., by etching). As with the dielectric layers 710, the non-contiguous arrangement of the areas of anti-reflection layer 714 cause the metal contacts to exhibit reduced capacitance relative to capacitance exhibited with a contiguous anti-reflection layer extending between two or more of the metal contacts 720 or dielectric layers 710 and the semiconductor material.

The anti-reflection layer 714 can comprise any suitable dielectric material that is compatible with the semiconductor material of the submount 700. Examples include metal oxides, nitrides, and oxynitrides and semiconductor oxides, nitrides, and oxynitrides. One specific example comprises an anti-reflection layer 714 comprising silicon nitride on a semiconductor submount comprising silicon (doped or undoped). The anti-reflection layer 714 can comprise a single quarter-wave (λ/4) layer at a selected wavelength within the operational wavelength range. For silicon nitride and an operation wavelength range of about 1.2-1.7 μm, the resulting thickness typically is between about 100 nm and about 300 nm, for example. Other materials or thicknesses can be employed, or the anti-reflection layer can be arranged for use over a different operational wavelength range. Other anti-reflection layer arrangements can be employed, e.g., a multi-layer antireflection coating.

FIGS. 16C, 17C, 18C, and 19C show measured capacitance exhibited by silicon optical submounts 700 with four metal contacts 720 shown in FIGS. 16A/B, 17A/B, 18A/B, and 19A/B, respectively. The largest measured capacitance (about 0.8 pF at zero bias voltage) is exhibited by the submount 700 with a contiguous silicon nitride layer 709 (168 nm thick) between all the metal contacts 720 and the semiconductor material (FIG. 16C). Dividing the silicon nitride into corresponding non-contiguous areas 710 beneath each metal contact 720 reduces the measured capacitance to about 0.4 pF (FIG. 17C). A submount 700 with contiguous silicon nitride (168 nm thick) and silicon oxide (2 μm thick) layers beneath the metal contacts exhibits measured capacitance of about 0.05 pF (FIG. 18C). A submount 700 with non-contiguous silicon nitride and silicon oxide layers (168 nm and 2 μm thick, respectively) exhibits the lowest measured capacitance (about 0.035 pF; FIG. 19C).

The semiconductor optical submounts shown in FIGS. 16A/B, 17A/B, 18A/B, and 19A/B each includes a recessed area 704a and one or more protruding areas 704b arranged as described above for facilitating use of a chip or die bonder. Any of the arrangements or adaptations disclosed above or shown in FIGS. 1-9 (for facilitating use of a chip or die bonder for placing and attaching a submount) can be combined in any suitable way with any of the arrangements or adaptations disclosed above or shown in FIGS. 10-19C (for reducing capacitance of metal contacts on a semiconductor submount); all such combinations shall fall within the scope of the present disclosure or appended claims.

Exemplary apparatus and methods encompassed by the present disclosure include, but are not limited to, the following examples:

### Example 1

An apparatus comprising a submount formed from a volume of solid submount material wherein: (a) a top surface of the submount includes one or more metal contacts formed on corresponding contact areas that are arranged for attaching a component to the top surface of the submount; (b) the one or more contact areas are positioned on a region of the submount top surface that is (i) recessed relative to one or more protruding regions of the submount top surface and (ii) sized and shaped to accommodate the attached component positioned at least partly within the recessed region; and (c) one or more of the protruding regions form a surface for engaging a pickup tool of a die bonder and enabling the die bonder to attach the submount to a substrate without substantial contact between the pickup tool and the recessed region.

### Example 2

The apparatus of Example 1 wherein: (d) the submount material is substantially transparent over an operational wavelength range; (e) the submount is arranged to direct or transmit a portion of an optical signal to propagate within the volume of semiconductor material so that at least a portion of the optical signal is transmitted through a transmission area of a top surface of the submount; and (f) the one or more metal contacts are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor.

### Example 3

The apparatus of Example 2 wherein the operational wavelength range extends from about 0.4 μm to about 2 μm.

### Example 4

The apparatus of Example 2 wherein the operation wavelength range extends from about 1.2 μm to about 1.7 μm.

### Example 5

The apparatus of any one of Examples 1-4 wherein the submount material is a semiconductor material.

### Example 6

The apparatus of Example 5 wherein the semiconductor material comprises a doped or undoped Group IV semiconductor, a doped or undoped III-V semiconductor, or a doped or undoped II-VI semiconductor.

### Example 7

The apparatus of Example 5 wherein the semiconductor material is doped or undoped silicon.

### Example 8

The apparatus of any one of Examples 1-4 wherein the submount material is a dielectric material.

### Example 9

The apparatus of Example 8 wherein the dielectric material comprises (i) a glassy material, (ii) a crystalline material, (iii) a ceramic material, (iv) a metal oxide, nitride, or oxynitride, or (v) a semiconductor oxide, nitride, or oxynitride.

### Example 10

The apparatus of Example 1 wherein the submount material is a metal or metal alloy.

### Example 11

The apparatus of any one of Examples 1-10 wherein the top surface of the submount includes one or more corresponding metal bumps on each contact area and each metal bump does not extend upward beyond the surface of the one or more protruding regions, thereby enabling the die bonder to attach the submount to the waveguide substrate without substantial contact between the pickup tool and the one or more metal bumps.

### Example 12

The apparatus of Example 11 wherein each metal bump comprises gold, aluminum, or solder.

### Example 13

The apparatus of any one of Examples 1-12 further comprising an electronic, optical, optoelectronic, or photonic component received at least partly within the recessed region and attached to the submount top surface via the metal contacts.

### Example 14

The apparatus of any one of Examples 1-13 wherein one or more of the metal contacts includes a wire-bonding area.

### Example 15

The apparatus of any one of Examples 1-14 wherein the one or more protruding regions include one or more portions of the volume of the submount material that protrude from the top surface.

### Example 16

The apparatus of any one of Examples 1-15 wherein the one or more protruding regions include material different from the submount material.

### Example 17

The apparatus of Example 16 wherein the one or more protruding regions include (i) a glassy material, (ii) a crystalline material, (iii) a ceramic material, (iv) a metal or metal alloy, (v) a semiconductor material, (vi) a metal oxide, nitride, or oxynitride, or (vii) a semiconductor oxide, nitride, or oxynitride.

### Example 18

A method for making the submount of any one of Examples 1-17, the method comprising: (a) forming a region of the submount top surface that is (i) recessed relative to one or more protruding regions of the submount top surface and (ii) sized and shaped to accommodate an attached component; and (b) forming on the recessed region one or more separate metal contacts on corresponding contact areas that are arranged for attaching the component to the top surface of the submount.

### Example 19

A method comprising: (a) using a pickup tool of a die bonder, engaging the surface formed by the one or more protruding areas of the submount of any one of Claims 1-17 without substantial contact between the pickup tool and the recessed region of the submount; (b) using the die bonder, positioning the submount engaged with the pickup tool at an attachment location on a substrate; (c) securing the submount to the substrate at the attachment location; and (d) disengaging the pickup tool from the submount.

### Example 20

An apparatus comprising an optical submount formed from a volume of semiconductor material that is substantially transparent over an operational wavelength range, wherein: (a) the submount is arranged to direct or transmit a portion of an optical signal to propagate within the volume of semiconductor material so that at least a portion of the optical signal is transmitted through a transmission area of a top surface of the submount; (b) the top surface of the submount includes two or more separate metal contacts formed on corresponding contact areas that are distinct from the transmission area and that are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor; (c) the top surface includes a corresponding area of a first dielectric layer between each metal contact and the semiconductor material; and (d) the areas of the first dielectric layer are non-contiguous thereby causing the metal contacts to exhibit reduced capacitance relative to capacitance exhibited with a single contiguous area of the first dielectric layer extending between two or more of the metal contacts and the semiconductor material.

### Example 21

The apparatus of Example 20 wherein the contact areas are arranged for attaching a photodetector to the top surface of the submount in a position that enables the photodetector to receive the transmitted portion of the optical signal that exits the submount through the transmission area.

### Example 22

The apparatus of Example 21 further comprising a photodetector attached to the top surface of the submount in a position that enables the photodetector to receive the transmitted portion of the optical signal that exits the submount through the transmission area.

### Example 23

The apparatus of Example 20 wherein the contact areas are arranged for attaching a light source to the top surface of the submount in a position that enables the light source to launch the optical signal so that a portion thereof enters the submount through the transmission area.

### Example 24

The apparatus of Example 20 further comprising a light source attached to the top surface of the submount in a position that enables the light source to launch the optical signal so that a portion thereof enters the submount through the transmission area.

### Example 25

The apparatus of any one of Examples 20-24 wherein the semiconductor material comprises a doped or undoped Group IV semiconductor, a doped or undoped III-V semiconductor, or a doped or undoped II-VI semiconductor.

### Example 26

The apparatus of any one of Examples 20-24 wherein the semiconductor material is doped or undoped silicon.

### Example 27

The apparatus of any one of Examples 20-26 wherein the operational wavelength range is between about 1.2 μm and about 1.7 μm.

### Example 28

The apparatus of any one of Examples 20-27 wherein one or more of the metal contacts includes a wire-bonding area.

### Example 29

The apparatus of any one of Examples 20-28 wherein the top surface of the submount includes a dielectric anti-reflection layer formed on the transmission area.

### Example 30

The apparatus of any one of Examples 20-29 wherein the first dielectric layer comprises a metal oxide or a semiconductor oxide.

### Example 31

The apparatus of any one of Examples 20-30 wherein the first dielectric layer is greater than about 1 μm thick.

### Example 32

The apparatus of any one of Examples 20-31 wherein the first dielectric layer is greater than about 2 μm thick.

### Example 33

The apparatus of any one of Examples 20-32 wherein the top surface of the submount includes a dielectric anti-reflection layer formed on the transmission area.

### Example 34

The apparatus of any one of Examples 20-29 wherein (i) the top surface of the submount includes a dielectric anti-reflection layer formed on the transmission area and (ii) the first dielectric layer and the dielectric anti-reflection layer have the same thickness and material composition.

### Example 35

The apparatus of any one of Examples 20-32 wherein (i) the top surface of the submount includes a dielectric anti-reflection layer formed on the transmission area and (ii) the first dielectric layer and the dielectric anti-reflection layer differ with respect to thickness or material composition.

### Example 36

The apparatus of Example 35 wherein (i) the top surface includes a corresponding additional area of the dielectric anti-reflection layer between each metal contact area and the corresponding area of the first dielectric layer and (ii) the additional areas of the dielectric anti-reflection layer are non-contiguous thereby causing the metal contacts to exhibit reduced capacitance relative to capacitance exhibited with a single contiguous area of the dielectric anti-reflection layer between the metal contacts and the areas of the first dielectric layer.

### Example 37

The apparatus of any one of Examples 33-36 wherein the dielectric anti-reflection layer comprises silicon nitride or silicon oxynitride.

### Example 38

The apparatus of any one of Examples 33-37 wherein the dielectric anti-reflection layer is a single quarter-wave layer for a selected wavelength within the operational wavelength range.

### Example 39

The apparatus of any one of Claims 33-38 wherein the dielectric anti-reflection layer is between about 100 nm and about 300 nm thick.

### Example 40

A method for making the optical submount of any one of Examples 20-39, the method comprising: (a) arranging the submount is to direct or transmit a portion of an optical signal to propagate within the volume of semiconductor material so that at least a portion of the optical signal is transmitted through a transmission area of the top surface of the submount, wherein the submount is formed from a volume of semiconductor material that is substantially transparent over an operational wavelength range; (b) forming on the top surface of the submount two or more separate metal contacts on corresponding contact areas that are distinct from the transmission area and that are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor; and (c) forming between each metal contact and the semiconductor material a corresponding area of the first dielectric layer, (d) wherein the areas of the first dielectric layer are non-contiguous thereby causing the metal contacts to exhibit reduced capacitance relative to capacitance exhibited with a single contiguous area of the first dielectric layer extending between two or more of the metal contacts and the semiconductor material.

### Example 41

The apparatus of any one of Examples 20-39 wherein: (e) the transmission area and the two or more contact areas are positioned on a region of the submount top surface that is (i) recessed relative to one or more protruding regions of the submount top surface and (ii) sized and shaped to accommodate the attached photodetector; and (f) one or more of the protruding regions form a surface for engaging a pickup tool of a die bonder and enabling the die bonder to attach the submount to the waveguide substrate without substantial contact between the pickup tool and the recessed region.

### Example 42

The apparatus of Example 41 wherein the top surface of the submount includes one or more corresponding metal bumps on each contact area and each metal bump does not extend upward beyond the surface of the one or more protruding regions, thereby enabling the die bonder to attach the submount to the waveguide substrate without substantial contact between the pickup tool and the one or more metal bumps.

### Example 43

The apparatus of Example 42 wherein each metal bump comprises gold, aluminum, or solder.

### Example 44

The apparatus of any one of Examples 41-43 wherein the one or more protruding regions include one or more portions of the volume of the semiconductor material that protrude from the top surface of the submount.

### Example 45

The apparatus of any one of Examples 41-43 wherein the one or more protruding regions include material different from the semiconductor material.

### Example 46

The apparatus of Example 45 wherein the one or more protruding regions include a glassy material, a crystalline material, a ceramic material, a metal oxide, or a semiconductor oxide.

### Example 47

A method for making the optical submount of any one of Examples 41-46, the method comprising: (a) arranging the submount is to direct or transmit a portion of an optical signal to propagate within the volume of semiconductor material so that at least a portion of the optical signal is transmitted through a transmission area of the top surface of the submount, wherein the submount is formed from a volume of semiconductor material that is substantially transparent over an operational wavelength range; (b) forming a region of the submount top surface that is (i) recessed relative to one or more protruding regions of the submount top surface and (ii) sized and shaped to accommodate an attached component; and (c) forming on the recessed region on the top surface of the submount two or more separate metal contacts on corresponding contact areas that are distinct from the transmission area and that are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor; and (d) forming between each metal contact and the semiconductor material a corresponding area of the first dielectric layer, (e) wherein the areas of the first dielectric layer are non-contiguous thereby causing the metal contacts to exhibit reduced capacitance relative to capacitance exhibited with a single contiguous area of the first dielectric layer extending between two or more of the metal contacts and the semiconductor material.

### Example 48

A method comprising: (a) using a pickup tool of a die bonder, engaging the surface formed by the one or more protruding areas of the submount of any one of Examples 41-46 without substantial contact between the pickup tool and the recessed region of the submount; (b) using the die bonder, positioning the submount engaged with the pickup tool at an attachment location on a substrate; (c) securing the submount to the substrate at the attachment location; and (d) disengaging the pickup tool from the submount.

It is intended that equivalents of the disclosed exemplary embodiments and methods shall fall within the scope of the present disclosure or appended claims. It is intended that the disclosed exemplary embodiments and methods, and equivalents thereof, may be modified while remaining within the scope of the present disclosure or appended claims.

In the foregoing Detailed Description, various features may be grouped together in several exemplary embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed exemplary embodiment. Thus, the appended claims are hereby incorporated into the Detailed Description, with each claim standing on its own as a separate disclosed embodiment. However, the present disclosure shall also be construed as implicitly disclosing any embodiment having any suitable set of one or more disclosed or claimed features (i.e., sets of features that are not incompatible or mutually exclusive) that appear in the present disclosure or the appended claims, including those sets that may not be explicitly disclosed herein. It should be further noted that the scope of the appended claims do not necessarily encompass the whole of the subject matter disclosed herein.

For purposes of the present disclosure and appended claims, the conjunction “or” is to be construed inclusively (e.g., “a dog or a cat” would be interpreted as “a dog, or a cat, or both”; e.g., “a dog, a cat, or a mouse” would be interpreted as “a dog, or a cat, or a mouse, or any two, or all three”), unless: (i) it is explicitly stated otherwise, e.g., by use of “either . . . or,” “only one of,” or similar language; or (ii) two or more of the listed alternatives are mutually exclusive within the particular context, in which case “or” would encompass only those combinations involving non-mutually-exclusive alternatives. For purposes of the present disclosure or appended claims, the words “comprising,” “including,” “having,” and variants thereof, wherever they appear, shall be construed as open ended terminology, with the same meaning as if the phrase “at least” were appended after each instance thereof.

In the appended claims, if the provisions of 35 USC §112 ¶6 are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC §112 ¶6 are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

1. An apparatus comprising a submount formed from a volume of solid submount material wherein:
(a) a top surface of the submount includes one or more metal contacts formed on corresponding contact areas that are arranged for attaching a component to the top surface of the submount;
(b) the one or more contact areas are positioned on a region of the submount top surface that is (i) recessed relative to one or more protruding regions of the submount top surface and (ii) sized and shaped to accommodate the attached component positioned at least partly within the recessed region; and
(c) one or more of the protruding regions form a surface for engaging a pickup tool of a die bonder and enabling the die bonder to attach the submount to a substrate without substantial contact between the pickup tool and the recessed region.

2. The apparatus of claim 1 wherein:
(d) the submount material is substantially transparent over an operational wavelength range;
(e) the submount is arranged to direct or transmit a portion of an optical signal to propagate within the volume of semiconductor material so that at least a portion of the optical signal is transmitted through a transmission area of a top surface of the submount; and
(f) the one or more metal contacts are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor.

3. The apparatus of claim 1 wherein the submount material is a semiconductor material.

4. The apparatus of claim 3 wherein the semiconductor material is doped or undoped silicon.

5. The apparatus of claim 1 wherein the submount material is a dielectric material.

6. The apparatus of claim 5 wherein the dielectric material comprises (i) a glassy material, (ii) a crystalline material, (iii) a ceramic material, (iv) a metal oxide, nitride, or oxynitride, or (v) a semiconductor oxide, nitride, or oxynitride.

7. The apparatus of claim 1 wherein the top surface of the submount includes one or more corresponding metal bumps on each contact area and each metal bump does not extend upward beyond the surface of the one or more protruding regions, thereby enabling the die bonder to attach the submount to the waveguide substrate without substantial contact between the pickup tool and the one or more metal bumps.

8. The apparatus of claim 7 wherein each metal bump comprises gold, aluminum, or solder.

9. The apparatus of claim 1 further comprising an electronic, optical, optoelectronic, or photonic component received at least partly within the recessed region and attached to the submount top surface via the metal contacts.

10. The apparatus of claim 1 wherein one or more of the metal contacts includes a wire-bonding area.

11. The apparatus of claim 1 wherein the one or more protruding regions include one or more portions of the volume of the submount material that protrude from the top surface.

12. The apparatus of claim 1 wherein the one or more protruding regions include material different from the submount material.

13. The apparatus of claim 12 wherein the one or more protruding regions include (i) a glassy material, (ii) a crystalline material, (iii) a ceramic material, (iv) a metal or metal alloy, (v) a semiconductor material, (vi) a metal oxide, nitride, or oxynitride, or (vii) a semiconductor oxide, nitride, or oxynitride.

14. An apparatus comprising an optical submount formed from a volume of semiconductor material that is substantially transparent over an operational wavelength range, wherein:
(a) the submount is arranged to direct or transmit a portion of an optical signal to propagate within the volume of semiconductor material so that at least a portion of the optical signal is transmitted through a transmission area of a top surface of the submount;
(b) the top surface of the submount includes two or more separate metal contacts formed on corresponding contact areas that are distinct from the transmission area and that are arranged for attaching an optoelectronic component to the top surface of the submount in a position that enables the component (i) to receive the transmitted portion of the optical signal that exits the submount through the transmission area or (ii) to launch the optical signal so that the transmitted portion thereof enters the submount through the transmission area to propagate within the volume of semiconductor;
(c) the top surface includes a corresponding area of a first dielectric layer between each metal contact and the semiconductor material; and
(d) the areas of the first dielectric layer are non-contiguous thereby causing the metal contacts to exhibit reduced capacitance relative to capacitance exhibited with a single contiguous area of the first dielectric layer extending between two or more of the metal contacts and the semiconductor material.

15. The apparatus of claim 14 wherein the contact areas are arranged for attaching a photodetector to the top surface of the submount in a position that enables the photodetector to receive the transmitted portion of the optical signal that exits the submount through the transmission area.

16. The apparatus of claim 15 further comprising a photodetector attached to the top surface of the submount in a position that enables the photodetector to receive the transmitted portion of the optical signal that exits the submount through the transmission area.

17. The apparatus of claim 14 wherein the contact areas are arranged for attaching a light source to the top surface of the submount in a position that enables the light source to launch the optical signal so that a portion thereof enters the submount through the transmission area.

18. The apparatus of claim 14 further comprising a light source attached to the top surface of the submount in a position that enables the light source to launch the optical signal so that a portion thereof enters the submount through the transmission area.

19. The apparatus of claim 14 wherein the semiconductor material is doped or undoped silicon.

20. The apparatus of claim 14 wherein one or more of the metal contacts includes a wire-bonding area.

21. The apparatus of claim 14 wherein the top surface of the submount includes a dielectric anti-reflection layer formed on the transmission area.

22. The apparatus of claim 14 wherein the first dielectric layer comprises a metal oxide or a semiconductor oxide.

23. The apparatus of claim 14 wherein the first dielectric layer is greater than about 1 μm thick.

24. The apparatus of claim 14 wherein the first dielectric layer is greater than about 2 μm thick.

25. The apparatus of claim 14 wherein the top surface of the submount includes a dielectric anti-reflection layer formed on the transmission area.

26. The apparatus of claim 14 wherein (i) the top surface of the submount includes a dielectric anti-reflection layer formed on the transmission area and (ii) the first dielectric layer and the dielectric anti-reflection layer have the same thickness and material composition.

27. The apparatus of claim 14 wherein (i) the top surface of the submount includes a dielectric anti-reflection layer formed on the transmission area and (ii) the first dielectric layer and the dielectric anti-reflection layer differ with respect to thickness or material composition.

28. The apparatus of claim 27 wherein (i) the top surface includes a corresponding additional area of the dielectric anti-reflection layer between each metal contact area and the corresponding area of the first dielectric layer and (ii) the additional areas of the dielectric anti-reflection layer are non-contiguous thereby causing the metal contacts to exhibit reduced capacitance relative to capacitance exhibited with a single contiguous area of the dielectric anti-reflection layer between the metal contacts and the areas of the first dielectric layer.

29. The apparatus of claim 14 wherein:
(e) the transmission area and the two or more contact areas are positioned on a region of the submount top surface that is (i) recessed relative to one or more protruding regions of the submount top surface and (ii) sized and shaped to accommodate the attached photodetector; and
(f) one or more of the protruding regions form a surface for engaging a pickup tool of a die bonder and enabling the die bonder to attach the submount to the waveguide substrate without substantial contact between the pickup tool and the recessed region.

30. The apparatus of claim 29 wherein the top surface of the submount includes one or more corresponding metal bumps on each contact area and each metal bump does not extend upward beyond the surface of the one or more protruding regions, thereby enabling the die bonder to attach the submount to the waveguide substrate without substantial contact between the pickup tool and the one or more metal bumps.

31. The apparatus of claim 30 wherein each metal bump comprises gold, aluminum, or solder.

32. The apparatus of claim 29 wherein the one or more protruding regions include one or more portions of the volume of the semiconductor material that protrude from the top surface of the submount.

33. The apparatus of claim 29 wherein the one or more protruding regions include material different from the semiconductor material.

34. The apparatus of claim 33 wherein the one or more protruding regions include a glassy material, a crystalline material, a ceramic material, a metal oxide, or a semiconductor oxide.
